(19) United States
(12) Patent Application Publication
(10) Pub. No.: US 2023/0171963 A1
(43) Pub. Date: Jun. 1, 2023

(54) SEMICONDUCTOR DEVICE

(71) Applicant: Samsung Electronics Co., Ltd., Suwon-si (KR)

(72) Inventors: Sungun Lee, Daegu (KR); Inmo Kim, Hwaseong-si (KR); Sujeong Kim, Seoul (KR)

(21) Appl. No.: 17/883,272

(22) Filed: Aug. 8, 2022

(30) Foreign Application Priority Data
Nov. 26, 2021 (KR) 10-2021-0165699
Dec. 30, 2021 (KR) 10-2021-0192680

(51) Int. Cl. H01L 27/11573; H01L 27/11519; H01L 27/11524; H01L 27/11526; H01L 27/11556; H01L 27/11565; H01L 27/1157; H01L 27/11582; G11C 5/06

(52) U.S. Cl. CPC H01L 27/11573; H01L 27/11519; H01L 27/11524; H01L 27/11526; H01L 27/11556; H01L 27/11565; H01L 27/1157; H01L 27/11582; G11C 5/06

(57) ABSTRACT

A semiconductor device includes a memory cell region including a plurality of memory cells disposed on a first semiconductor substrate and including gate electrodes stacked to be spaced apart from each other on the first semiconductor substrate and channel structures passing through the gate electrodes and connected to the first semiconductor substrate, a peripheral circuit region including a first conductivity-type impurity, disposed on a second semiconductor substrate having an upper surface facing each other in a first direction, perpendicular to an upper surface of the first semiconductor substrate, and including peripheral circuits controlling the plurality of memory cells, wherein the peripheral circuits include a plurality of well regions formed in the second semiconductor substrate, an ion implantation region disposed between the plurality of well regions and including the first conductivity-type impurity, and a plurality of antenna diodes, and at least one of the plurality of antenna diodes overlaps the ion implantation region in the first direction. Accordingly, in the semiconductor device according to an exemplary embodiment of the present inventive concept, an antenna diode may be inserted, while minimizing an increase in an interval between the plurality of well regions, and further, peripheral circuits may be integrated and wiring complexity may be reduced.

### CROSS-REFERENCE TO RELATED APPLICATION(S)

This application claims benefit of priority to Korean Patent Application Nos. 10-2021-0165699 filed on Nov. 26, 2021 and 10-2021-0192680 filed on Dec. 30, 2021, in the Korean Intellectual Property Office, the disclosures of which are incorporated herein by reference in their entirety.

### BACKGROUND

The present inventive concept relates to a semiconductor device.

A semiconductor device manufacturing process includes a plurality of unit processes, and various methods have been proposed to protect semiconductor devices, which have been already formed, while the plurality of unit processes are conducted. In order to minimize damage to semiconductor devices already formed in the unit processes, various protective elements may be additionally formed on a semiconductor substrate. For example, a semiconductor device is manufactured to include a transistor and an antenna diode in a predetermined region of the semiconductor substrate. The antenna diode protects the transistor from plasma damage by naturally emitting plasma ions to the semiconductor substrate during a manufacturing process of the semiconductor device. However, considering that as many semiconductor elements as possible should be arranged in a limited area, the degree of integration of the semiconductor device may be lowered due to the arrangement of the protective elements or the degree of freedom of design may be reduced due to an increase in complexity of metal wiring.

### SUMMARY

An aspect of the present inventive concept is to provide an integrated semiconductor device in which an antenna diode is formed above an ion implantation region, thereby minimizing an increase in a gap between a plurality of well regions and reducing the complexity of metal wiring.

According to an aspect of the present inventive concept, a semiconductor device includes: a memory cell region including a plurality of memory cells disposed on a first semiconductor substrate and including gate electrodes stacked to be spaced apart from each other on the first semiconductor substrate and channel structures passing through the gate electrodes and connected to the first semiconductor substrate; a peripheral circuit region including a first conductivity-type impurity, disposed on a second semiconductor substrate having an upper surface facing to an upper surface of the first semiconductor substrate in a first direction, perpendicular to the upper surface of the first semiconductor substrate, and including peripheral circuits controlling the plurality of memory cells, wherein the peripheral circuits include a plurality of well regions formed in the second semiconductor substrate, an ion implantation region disposed between the plurality of well regions and including the first conductivity-type impurity, and a plurality of antenna diodes, and at least one of the plurality of antenna diodes overlaps the ion implantation region in the first direction.

According to another aspect of the present inventive concept, a semiconductor device includes: a plurality of well regions formed on a semiconductor substrate including a first conductivity-type impurity and including a first well region including the first conductivity-type impurity and a second well region including a second conductivity-type impurity, different from the first conductivity-type impurity; an ion implantation region disposed between the plurality of well regions and including the first conductivity-type impurity; a plurality of antenna diodes including a first antenna diode formed in the first well region and a second antenna diode disposed on the ion implantation region; and a plurality of transistors, each of the plurality of transistors being defined by an active region included in the plurality of well regions and a gate structure formed on the active region.

According to another aspect of the present inventive concept, a semiconductor device includes: a plurality of well regions formed in a semiconductor substrate including a first conductivity-type impurity; an ion implantation region disposed between the plurality of well regions and including the first conductivity-type impurity; a plurality of antenna diodes, at least one of the plurality of antenna diodes being disposed on the ion implantation region; and a plurality of transistors, each of the plurality of transistors being defined by an active region included in the plurality of well regions and a gate structure formed on the active region, the gate structure being electrically connected to a most adjacent antenna diode, among the plurality of antenna diodes, by a metal wiring.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a top view of a semiconductor device in which an antenna diode is disposed;

FIG. 2 is a view illustrating a method for disposing an antenna diode in a semiconductor device;

FIG. 3 is a schematic cross-sectional view of a semiconductor device in which an antenna diode is disposed according to the method illustrated in FIG. 2;

FIG. 4 is a view illustrating a problem that may occur in a semiconductor device according to an embodiment of the present inventive concept;

FIG. 5 is a cross-sectional view of a semiconductor device according to an example embodiment;

FIG. 6 is a top view of a semiconductor device according to an example embodiment in which an antenna diode is disposed;

FIG. 7 is a view illustrating a method for disposing an antenna diode in a semiconductor device according to an embodiment of the present inventive concept;

FIG. 8 is a cross-sectional view schematically illustrating a semiconductor device in which an antenna diode is disposed according to the method illustrated in FIG. 7;

FIG. 9 is a cross-sectional view illustrating a semiconductor device according to an embodiment of the present inventive concept;

FIG. 10 is a cross-sectional view illustrating a semiconductor device according to an embodiment of the present inventive concept;

FIG. 11 is a top view illustrating an application example of a semiconductor device according to an embodiment of the present inventive concept;

FIGS. 12 to 14 are diagrams illustrating characteristics of an antenna diode included in a semiconductor device according to an embodiment of the present inventive concept; and

FIG. 15 is a block diagram illustrating an electronic device including a semiconductor device according to an example embodiment.

### DETAILED DESCRIPTION

Hereinafter, example embodiments of the present inventive concept will be described with reference to the accompanying drawings.

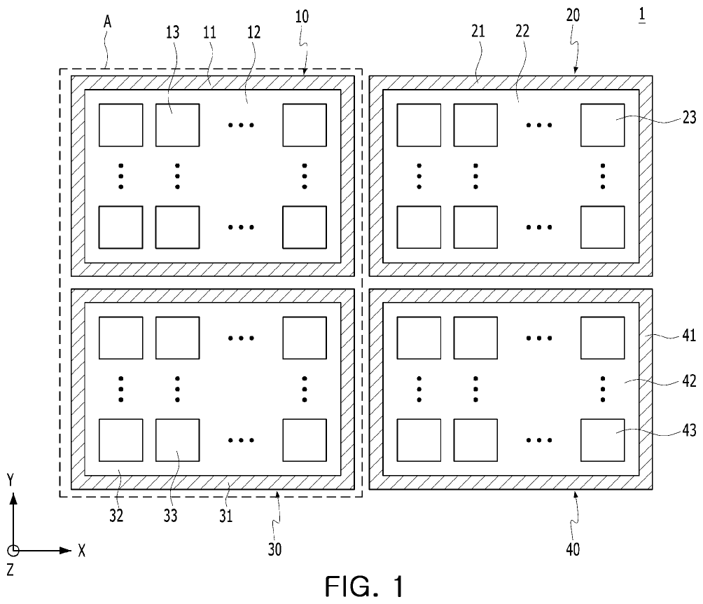

FIG. 1 is a top view of a semiconductor device in which an antenna diode is disposed.

Referring to FIG. 1, a semiconductor device 1 may include a plurality of regions 10, 20, 30, and 40. Among the plurality of regions 10, 20, 30, and 40, adjacent regions 10, 20, 30, and 40 may include well regions 12, 22, 32, and 42 doped with impurities of different conductivity types. For example, the first region 10 and the fourth region 40 may include a P-well region in which an NMOS transistor is formed, and the second region 20 and the third region 30 may include an N-well region in which a PMOS transistor is formed. However, this is only an example embodiment and the present inventive concept is not limited thereto.

The plurality of regions 10, 20, 30, and 40 may include ion implantation regions 11, 21, 31, and 41 for preventing an occurrence of a breakdown voltage due to interference between the plurality of well regions 12, 22, 32, and 42. The ion implantation regions 11, 21, 31, and 41 may be formed to surround the plurality of well regions 12, 22, 32, and 42.

The ion implantation regions 11, 21, 31, and 41 of the semiconductor device may be formed by a method of intensively doping a first conductivity-type impurity into a semiconductor substrate doped with the first conductivity-type impurity. In this case, a doping concentration of the ion implantation regions 11, 21, 31, and 41 may be higher than that of the semiconductor substrate. For example, the first conductivity type impurity may be a P-type dopant, and when the semiconductor substrate is P-doped, the ion implantation regions 11, 21, 31, and 41 may be P+-doped. However, this is only an example embodiment and the present inventive concept is not limited thereto.

The plurality of well regions 12, 22, 32, and 42 may include element regions 13, 23, 33, and 43 in which a plurality of semiconductor elements may be formed. The types of the plurality of semiconductor elements formed in the element regions 13, 23, 33, and 43 may be determined by the conductivity types of the well regions 12, 22, 32, and 42 respectively formed in the plurality of regions 10, 20, 30 and 40.

The plurality of semiconductor elements may include transistors having a gate structure and an active region. The gate structure may be erected in a first direction (e.g., a Z-direction), perpendicular to an upper surface of the semiconductor substrate on which the semiconductor device 1 is formed. In order to prevent the gate structure from collapsing in subsequent processes performed after forming the active region and the gate structure, the gate structure may have to be disposed at predetermined reference intervals. In addition, an antenna diode connected to the gate structure may be disposed in the semiconductor device 1 in order to prevent damage to the gate structure occurring in an etching process using plasma or the like.

The antenna diode may protect semiconductor elements may naturally emit plasma ions accumulated to form various patterns during a semiconductor manufacturing process into the semiconductor substrate, thereby protecting semiconductor elements such as transistors from plasma damage.

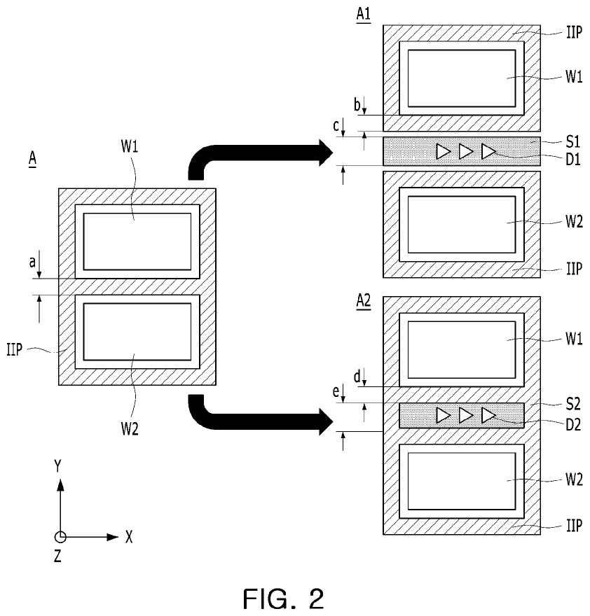

FIG. 2 is a view illustrating a method for disposing an antenna diode in a semiconductor device.

Referring to FIG. 2, region A including adjacent well regions W1 and W2 may correspond to region A illustrated in FIG. 1. In other words, the well regions W1 and W2 adjacent to each other may be separated from each other by an ion implantation region IIP. However, the well regions W1 and W2 adjacent to each other may be N-well regions.

In this case, a thickness of the ion implantation region IIP separating the adjacent well regions W1 and W2 may be a. For example, a may have a value between about 4.6 um and about 5.0 um. However, this is only an example embodiment and the present inventive concept may not be limited thereto. As an example, although a, as illustrated in region A of FIG. 2, indicates the thickness of the ion implantation region IIP, a may be a distance between adjacent well regions W1 and W2.

In general, in a semiconductor device, separate diode active regions S1 and S2 separated from a plurality of semiconductor elements may be formed, and an antenna diode D may be formed in the diode active regions S1 and S2. In this case, the diode active regions S1 and S2 may be formed in a region without the ion implantation region IIP, and gate structures constituting the plurality of semiconductor elements may be connected to the antenna diodes D formed in the diode active regions S1 and S2.

Meanwhile, as the diode active regions S1 and S2 are formed, an interval between the gate structures included in the plurality of semiconductor elements may increase. The interval between the plurality of semiconductor elements included in the semiconductor device may have a direct effect on the performance of the semiconductor device, and thus there may be a limitation in reducing the size of the semiconductor device. Accordingly, the degree of integration of the semiconductor device may be lowered by the diode active regions S1 and S2 for arranging the antenna diode D.

For example, in a region A1 including the well regions W1 and W2 adjacent to each other, the diode active region Si in which the antenna diode D is formed may be a P-well region doped with impurities of a conductivity type different from that of the adjacent well regions W1 and W2, for example, a P-type dopant. In the region A1, the diode active region S1 may be formed between the ion implantation regions IIP.

In this case, a thickness of each of the ion implantation regions IIP disposed on both sides of the diode active region S1 may be b. For example, b may have a value between about 4.4 um and 4.8 um. However, this is only an example embodiment and the present inventive concept is not limited thereto. For example, b illustrated in the region A1 of FIG. 2 is illustrated as indicating the thickness of the ion implantation region IIP, but b may be a distance between each of the well regions W1 and W2 and the diode active region S1.

Meanwhile, a thickness of the diode active region S1 in which the antenna diode D is formed may be c. For example, c may have a value between about 2.8 um and 3.2 um. However, this is only an example embodiment and the present inventive concept may not be limited. For example, the thickness c of the diode active region S1 may be formed to be smaller than 2.8 um for integration of the semiconductor device or may be formed to be greater than 3.2 um for a stable operation of the semiconductor device.

Accordingly, the interval between the adjacent well regions W1 and W2 in the region A1 may correspond to the sum of twice b and c. The interval between the adjacent well regions W1 and W2 may be between about 11.6 um and 12.8 um, and may be, for example, about 12.2 um. Accordingly, compared to a case in which the antenna diode D is not additionally disposed, the interval between the well regions W1 and W2 adjacent to each other may be increased by about 2.4 times or more.

Meanwhile, in the region A2 including the adjacent well regions W1 and W2, the diode active region S2 in which the antenna diode D is formed may be a region in which a portion of the ion implantation region IIP is removed.

In this case, a thickness of each of the ion implantation regions IIP disposed on both sides of the diode active region S2 may be d. For example, d may have a value between about 4.0 um and 4.4 um. However, this is only an example embodiment and the present inventive concept may not be limited. For example, although d illustrated in the region A2 of FIG. 2 is illustrated as indicating the thickness of the ion implantation region IIP, d may be an interval between each of the well regions W1 and W2 and the diode active region S2.

Meanwhile, the thickness of the diode active region S2 in which the antenna diode D is formed may be e. For example, the thickness of the diode active region S2 may be a thickness in a second direction (e.g., a Y-direction) of the antenna diode D, and e may have a value between about 0.2 um and 0.5 um. However, this is only an example embodiment and the present inventive concept may not be limited thereto. For example, the thickness e of the diode active region S2 may be formed to be smaller than 0.2 um for the integration of the semiconductor device or may be formed to be greater than 0.5 um for a stable operation of the semiconductor device.

Accordingly, the interval between the adjacent well regions W1 and W2 in the region A2 may correspond to the sum of twice d and e. An interval between the adjacent well regions W1 and W2 may be between about 8.2 um and 9.3 um, for example, about 8.6 um. Accordingly, compared to a case in which the antenna diode D is not additionally disposed, the interval between the adjacent well regions W1 and W2 may be increased by about 1.7 times or more.

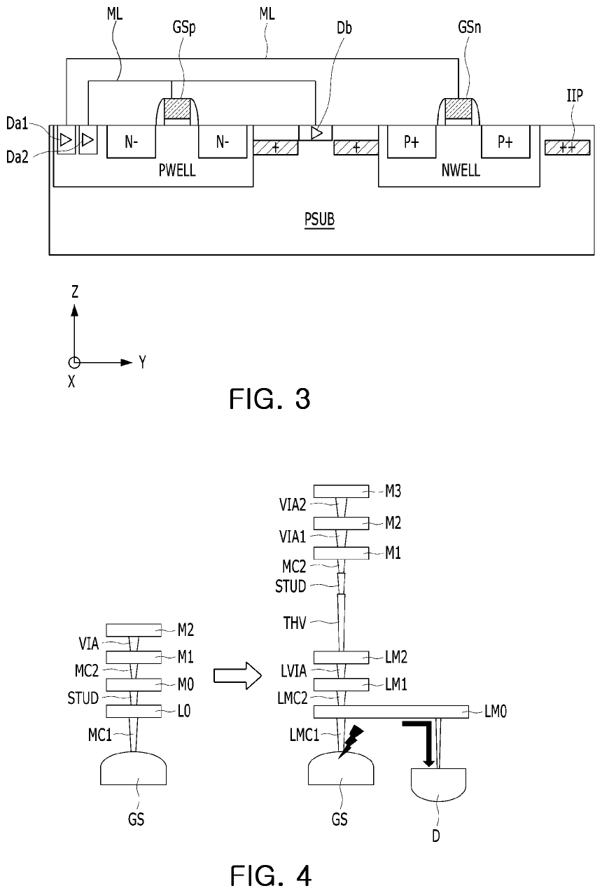

FIG. 3 is a schematic cross-sectional view of a semiconductor device in which an antenna diode is disposed according to the method illustrated in FIG. 2.

Referring to FIG. 3, a semiconductor device in which an antenna diode Db is disposed by applying the diode active region S2 of the region A2 illustrated in FIG. 2 may include a plurality of well regions PWELL and NWELL formed in a semiconductor substrate PSUB, an ion implantation region IIP, a plurality of antenna diodes Da1, Da2, and Db, and a plurality of transistors.

The semiconductor substrate PSUB may include a first conductivity-type impurity, for example, a P-type dopant, and the ion implantation region IIP may be disposed between the plurality of well regions PWELL and NWELL and have a first conductivity-type impurity. A plurality of transistors defined by an active region included in the plurality of well regions PWELL and NWELL and gate structures GSn and GSp formed thereon may be formed on the semiconductor substrate PSUB.

Meanwhile, the antenna diodes Da1, Da2, and Db for protecting the plurality of transistors may include first antenna diodes Da1 and Da2 formed in the first well region PWELL including the first conductivity-type impurity, among the plurality of well regions PWELL and NWELL and a second antenna diode Db formed in the diode active region between the plurality of well regions PWELL and NWELL.

In this case, the diode active region may not overlap the ion implantation region IIP in the first direction (e.g., the Z-direction). Accordingly, the ion implantation region IIP may be discontinuously disposed between the plurality of well regions PWELL and NWELL.

The antenna diodes Da1, Da2, and Db may be connected to an upper metal wiring ML through a plurality of contacts. The metal wiring ML may extend to upper portions of the gate structures GSn and GSp of the transistor in the second direction (e.g., the Y-direction). The gate structures GSn and GSp of the transistor may be connected to the antenna diodes Da1, Da2, and Db through a contact and the metal wiring ML.

Therefore, when electric charges or current are generated due to discharge in a subsequent process of the semiconductor device using plasma, etc., the generated charges or current flow to the antenna diodes Da1, Da2, and Db, thereby minimizing damage to the gate structures GSn and GSp.

FIG. 4 is a view illustrating a problem that may arise in a semiconductor device according to an embodiment of the present inventive concept.

Metal wirings and the gate structure GS illustrated in FIG. 4 may be included in a memory device, for example, a memory device including NAND flash memory cells. In a related art memory semiconductor device, the gate structure GS may be electrically connected to metal wirings L0, M0, M1, and M2 disposed thereon. In this case, the gate structure GS and the metal wirings L0, M0, M1, and M2 may be connected through a via VIA, contacts MC1 and MC2, and a stud STUD.

Meanwhile, the semiconductor device according to an embodiment of the present inventive concept may be a memory semiconductor device having a cell on peri (COP) structure. The memory semiconductor device having a COP structure may be manufactured so that a memory cell region and a peripheral circuit region have a stacked structure.

For example, the upper metal wirings M1, M2, and M3 included in the memory cell region may be connected to each other by the upper vias VIA1 and VIA2, an upper contact MC2, and a stud STUD, and the lower metal interconnections LM0, LM1, and LM2 included in the peripheral circuit region may be electrically connected to the gate structure GS by the lower vias LVIA and the lower contacts LMC1 and LMC2. Meanwhile, the memory cell region and the peripheral circuit region may be connected to each other by a connection portion THV.

As described above, the memory semiconductor device having a COP structure uses a large amount of metal wirings compared to an existing structure, so that the amount of plasma-induced charge accumulated in the semiconductor devices may increase when an etching process is performed. Accordingly, the necessity of the antenna diode D described above may increase to protect the semiconductor devices, particularly, a gate oxide layer of a low-voltage transistor, from plasma damage.

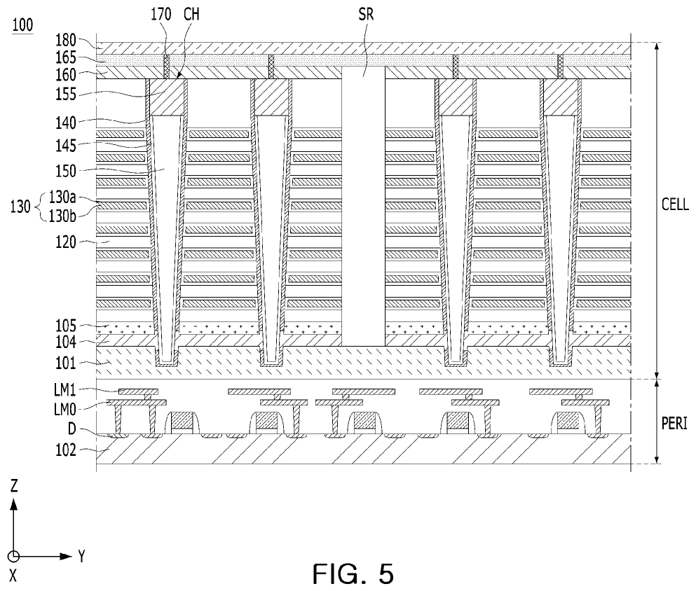

FIG. 5 is a cross-sectional view of a semiconductor device according to an example embodiment.

Referring to FIG. 5, the semiconductor device according to an embodiment of the present inventive concept may be a memory semiconductor device 100, and the memory semiconductor device 100 may include a memory cell region CELL in which data is stored and a peripheral circuit region PERI disposed below the memory cell region CELL.

In the memory semiconductor device 100 according to an example embodiment illustrated in FIG. 5, the memory cell region CELL may include a first semiconductor substrate 101, a plurality of insulating layers 120, a plurality of gate electrodes 130, a first conductive layer 104, a second conductive layer 105, channel structures CH, and an separation region SR.

In the memory semiconductor device 100 according to an embodiment, a direction (e.g., the Z-direction), perpendicular to an upper surface of the first semiconductor substrate 101, may be defined as a first direction. In this case, the first semiconductor substrate 101 may have an upper surface extending in a second direction (e.g., the Y-direction) and a third direction (e.g., an X-direction).

The first semiconductor substrate 101 may include a semiconductor material, for example, a group IV semiconductor, a group III-V compound semiconductor, or a group II-VI oxide semiconductor. For example, the group IV semiconductor may include silicon, germanium, or silicon-germanium. However, a configuration of the first semiconductor substrate 101 is not limited thereto, and the first semiconductor substrate 101 may be provided as an epitaxial layer, a silicon on insulator (SOI) layer, a semiconductor on insulator (SeOI) layer, or the like.

The memory semiconductor device 100 according to an embodiment may include insulating layers 120 and gate electrodes 130 spaced apart and alternately stacked in the first direction (e.g., Z-direction), perpendicular to the upper surface of the first semiconductor substrate 101, on the first semiconductor substrate 101. The insulating layers 120 may include an insulating material such as silicon oxide or silicon nitride.

The gate electrodes 130 may include a first gate layer 130a and a second gate layer 130b, respectively. For example, the first gate layer 130a may include tungsten nitride (WN), tantalum nitride (TaN), titanium nitride (TiN), or a combination thereof. Also, the second gate layer 130b may include a metal material, for example, tungsten (W). However, a configuration of the gate electrodes 130 is not limited thereto, and the gate electrodes 130 may be formed of three or more layers, and may include polycrystalline silicon or a metal silicide material.

Meanwhile, the first conductive layer 104 and the second conductive layer 105 may be sequentially stacked on the upper surface of the first semiconductor substrate 101. At least a portion of the first semiconductor substrate 101, the first conductive layer 104, and the second conductive layer 105 may function as a common source line in the memory semiconductor device 100 according to an embodiment of the present inventive concept. The first conductive layer 104 and the second conductive layer 105 may include a semiconductor material, for example, polycrystalline silicon. For example, at least the first conductive layer 104 may be doped with an impurity, and the second conductive layer 105 may be doped with an impurity or may include the impurity diffused from the first conductive layer 104.

In the memory semiconductor device 100 according to the embodiment, each of the channel structures CH may extend in the first direction and may be disposed to pass through the gate electrodes 130 and the insulating layers 120. However, this is only an example embodiment and the present inventive concept is not limited to that illustrated in FIG. 3, and the channel structures CH may be disposed to pass through at least a portion of the first semiconductor substrate 101. Meanwhile, the channel structures CH may be disposed to be spaced apart from each other in a horizontal direction on the upper surface of the first semiconductor substrate 101, while forming rows and columns on the first semiconductor substrate 101. Meanwhile, each of the channel structures CH may have a pillar shape having a side surface, perpendicular to the upper surface of the first semiconductor substrate 101 or an inclined side surface narrowing toward the first semiconductor substrate 101 according to an aspect ratio.

In the memory semiconductor device 100 according to the embodiment of the present inventive concept, each of the channel structures CH may include a channel layer 145, a channel insulating layer 150, and a pad layer 155. For example, each of the channel structures CH may further include a gate dielectric layer 140 disposed between the channel layer 145 and the gate electrodes 130 and including a plurality of layers for trapping charges. Meanwhile, a portion of the gate dielectric layer 140 may be removed from the bottom of each of the channel structures CH, and the channel layer 145 may be electrically connected to the first conductive layer 104 in the removed region.

In the memory semiconductor device 100 according to an embodiment, the channel layer 145 may include a semiconductor material such as polycrystalline silicon or single crystal silicon. The channel layer 145 may implement memory cell strings including a plurality of memory cells.

In the memory semiconductor device 100 according to an embodiment, the separation region SR may extend in the first direction and the second direction and may pass through the gate electrodes 130 and the insulating layers 120 that are alternately stacked. The separation region SR may include an insulating material, for example, silicon oxide. For example, the gate electrodes 130 may be disposed to be separated from each other in the third direction by the separation region SR.

In addition, the memory cell region CELL of the memory semiconductor device 100 may further include a first interlayer insulating layer 160, a second interlayer insulating layer 165, a contact plug 170 electrically connected to the channel structures CH., and a bit line 180 electrically connected to the contact plug 170. For example, the first interlayer insulating layer 160 and the second interlayer insulating layer 165 may cover the insulating layers 120 and the gate electrodes 130 and may include an insulating material such as silicon oxide. The contact plug 170 may pass through the first interlayer insulating layer 160 and the second interlayer insulating layer 165 and may electrically connect a bit line 180 and channel structures CH disposed on the second interlayer insulating layer 165.

The memory semiconductor device 100 according to an example embodiment may be formed by first manufacturing the peripheral circuit region PERI and then manufacturing the first semiconductor substrate 101 of the memory cell region CELL on the peripheral circuit region PERI. The first semiconductor substrate 101 may have the same size as that of the second semiconductor substrate 102 of the peripheral circuit region PERI or may be formed to be smaller than the second semiconductor substrate 102.

The peripheral circuit region PERI may include a second semiconductor substrate 102, circuit elements disposed on the second semiconductor substrate 102 and driving and controlling a plurality of memory cells, circuit contact plugs, and a plurality of metal wirings LM0 and LM1. For example, the circuit elements included in the peripheral circuit region PERI may include planar transistors. Meanwhile, each of the circuit elements may include a circuit gate dielectric layer, a spacer layer, and a circuit gate electrode, and active regions may be disposed in the second semiconductor substrate 102 on both sides of the circuit gate electrode. The active regions may serve as source/drain regions.

In the memory semiconductor device 100 of the present inventive concept, the plurality of metal wirings LM0 and LM1 are metal wirings disposed below the memory cells and may be distinguished from the metal wirings disposed above the memory cells. However, this is only an example embodiment, and an arrangement and shape of the plurality of metal wirings LM0 and LM1 is not limited to that illustrated in FIG. 5, and the number, position, and structure of the plurality of metal wirings LM0 and LM1 may vary according to an embodiment.

The memory cell region CELL and the peripheral circuit region PERI may be connected to each other in a region not illustrated. For example, in the memory semiconductor device 100 according to an embodiment of the present inventive concept, the peripheral circuit region PERI may be electrically connected to the memory cell region CELL through a connection portion. For example, the connection portion may be a through-hole via (THV).

According to an embodiment of the present inventive concept, the peripheral circuit region PERI may include circuit elements and the antenna diode D formed on the second semiconductor substrate 102 including a first conductivity-type impurity. The antenna diode may be electrically connected to a gate structure of a circuit element, such as a transistor. However, the structure of the memory semiconductor device 100 illustrated in FIG. 5 is merely an example embodiment and may not be limited to the illustrated structure.

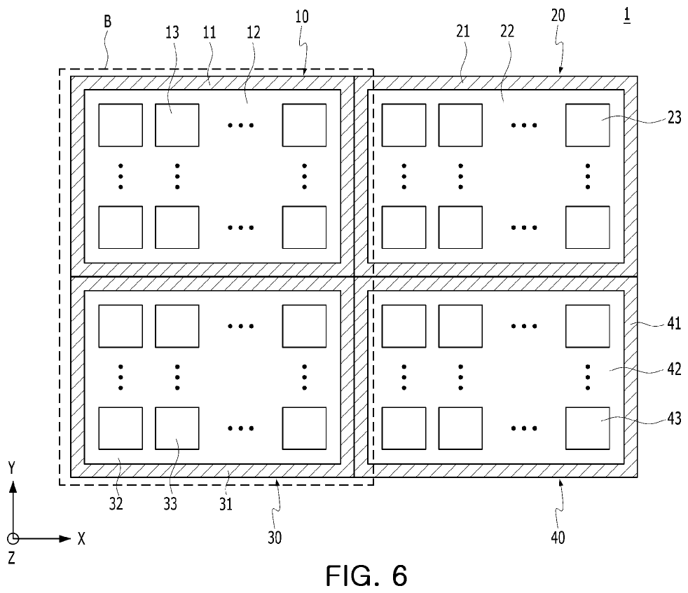

FIG. 6 is a top view of a semiconductor device according to an example embodiment in which an antenna diode is disposed.

FIG. 6 may correspond to a top view of the semiconductor device illustrated in FIG. 1. Meanwhile, FIG. 6 may illustrate a region corresponding to a portion of a peripheral circuit region of the memory semiconductor device.

Referring to FIG. 6, the semiconductor device 1 according to an example embodiment may include a plurality of regions 10, 20, 30, and 40. The plurality of regions 10, 20, 30, and 40 may include a plurality of well regions 12, 22, 32, and 42 and ion implantation regions 11, 21, 31, and 41 for preventing an occurrence of a breakdown voltage due to interference between the plurality of well regions 12, 22, 32, and 42. The ion implantation regions 11, 21, 31, and 41 may be formed to surround the plurality of well regions 12, 22, 32, and 42.

In a semiconductor device according to an embodiment of the present inventive concept, the ion implantation regions 11, 21, 31, and 41 may be formed by a method of intensively doping a first conductivity-type impurity in a semiconductor substrate doped with a first conductivity-type impurity. In this case, a doping concentration of the ion implantation regions 11, 21, 31, and 41 may be higher than that of the semiconductor substrate. For example, the first conductivity-type impurity may be a P-type dopant, and when the semiconductor substrate is P-doped, the ion implantation regions 11, 21, 31, and 41 may be P+-doped. However, this is only an example embodiment and the present inventive concept may not be limited thereto.

The plurality of well regions 12, 22, 32, and 42 may include element regions 13, 23, 33, and 43 in which a plurality of semiconductor elements may be formed. Types of the plurality of semiconductor elements formed in the element regions 13, 23, 33, and 43 may be determined by a conductivity type of the well regions 12, 22, 32, and 42 formed in the plurality of regions 10, 20, 30 and 40, respectively.

The plurality of semiconductor elements may include transistors having a gate structure and an active region. The gate structure may be erected in a first direction (e.g., the Z-direction) perpendicular to an upper surface of the semiconductor substrate on which the semiconductor device 1 is formed. The semiconductor device 1 according to an embodiment of the present inventive concept may include an antenna diode connected to the gate structure in order to prevent damage to the gate structure occurring in an etching process using plasma or the like.

However, unlike the semiconductor device illustrated in FIG. 1, in the semiconductor device 1 according to an embodiment of the present inventive concept, an antenna diode may be installed on the ion implantation regions 11, 21, 31, and 41 without a separate diode active region. Accordingly, in the semiconductor device 1 according to an embodiment of the present inventive concept, an increase in the interval between the well regions 12, 22, 32, and 42 as the antenna diode is disposed may be minimized.

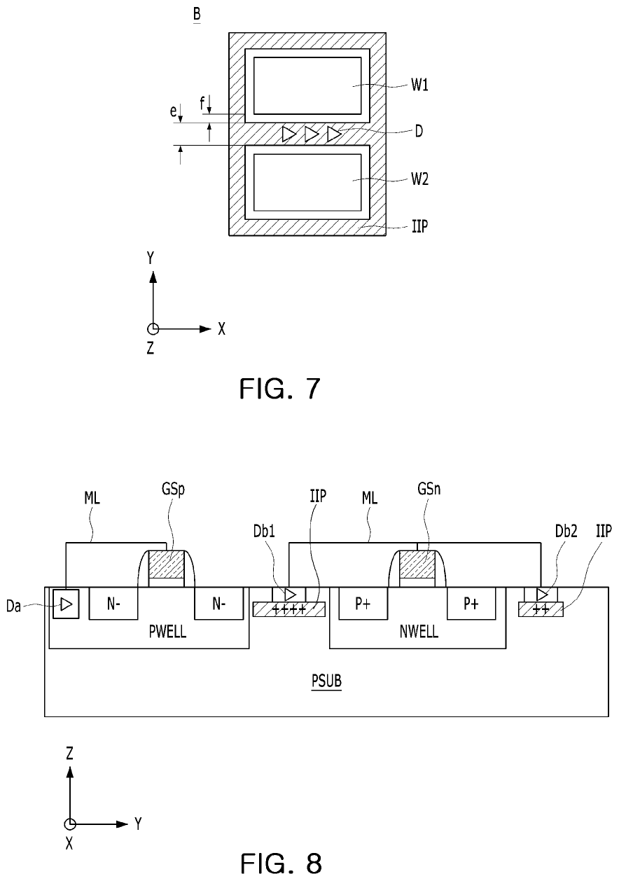

FIG. 7 is a view illustrating a method for disposing an antenna diode in a semiconductor device according to an embodiment of the present inventive concept.

Referring to FIG. 7, region B including adjacent well regions W1 and W2 may correspond to the region B illustrated in FIG. 6. In other words, the well regions W1 and W2 adjacent to each other may be separated from each other by the ion implantation region IIP. For example, the well regions W1 and W2 adjacent to each other may be N-well regions.

In this case, a thickness of the ion implantation region IIP in which the antenna diode D is disposed may be e. However, this is only an example embodiment and the present inventive concept may not be limited thereto, and e may be defined as a thickness of the antenna diode D in the second direction (e.g., the Y-direction). For example, e may be equal to the thickness e of the diode active region S2 or the antenna diode D illustrated in FIG. 2. For example, e may have a value between about 0.2 um and 0.5 um. However, the thickness of the antenna diode D may vary as needed.

Meanwhile, an interval between each of the adjacent well regions W1 and W2 and the ion implantation region IIP in which the antenna diode D is disposed may be f. However, this is only an example embodiment and the present inventive concept may not be limited thereto, and f may be defined as a distance between each of the adjacent well regions W1 and W2 and the antenna diode D. For example, f may have a value between about 3.0 um and 3.4 um.

Accordingly, in the region B, an interval between the adjacent well regions W1 and W2 may correspond to the sum of twice f and e. The interval between the adjacent well regions W1 and W2 may be between about 6.2 um and 7.3 um, for example, about 6.6 um. Accordingly, compared to a case in which the antenna diode D is not additionally disposed, the interval between the well regions W1 and W2 adjacent to each other may increase by about 1.5 times or less.

In addition, in the semiconductor device according to an embodiment of the present inventive concept, the interval between the adjacent well regions W1 and W2 may be reduced by about 20% to 30%, compared to the case of using the diode active region. Accordingly, in the semiconductor device according to an embodiment of the present inventive concept, the antenna diode D for protecting the gate oxide layer of the transistor may be inserted, while minimizing an increase in the interval between the adjacent well regions W1 and W2.

FIG. 8 is a cross-sectional view schematically illustrating a semiconductor device in which an antenna diode is disposed according to the method illustrated in FIG. 7.

Referring to FIG. 8, a semiconductor device according to an embodiment of the present inventive concept may include a plurality of well regions PWELL and NWELL, an ion implantation region IIP, a plurality of antenna diodes Da, Db1, and Db2, and a plurality of transistors formed in a semiconductor substrate PSUB. FIG. 8 may only illustrate main components of the semiconductor device for convenience of description. Accordingly, the illustrated main components and the arrangement of the metal wiring ML are merely an example and may not be limited.

The semiconductor substrate PSUB may include a first conductivity-type impurity, for example, a P-type dopant, and the ion implantation region IIP may be disposed between the plurality of well regions PWELL and NWELL and may include a first conductivity-type impurity. The plurality of well regions PWELL and NWELL include a first well region PWELL including a first conductivity-type impurity and a second well region NWELL including a second conductivity-type impurity different from the first conductivity type. For example, the first conductivity-type impurity may be a P-type dopant, and the second conductivity-type impurity may be an N-type dopant.

A concentration of the first conductivity-type impurity included in the ion implantation region IIP may be different depending on a position. Meanwhile, a doping concentration of the ion implantation region IIP may be higher than a doping concentration of the plurality of well regions PWELL and NWELL, in particular, the first well region PWELL.

A plurality of transistors defined by an active region included in the plurality of well regions PWELL and NWELL and gate structures GSn and GSp formed thereon may be formed on the semiconductor substrate PSUB. In the semiconductor device according to the embodiment of the present inventive concept, the antenna diodes Da, Db1, and Db2 may be configured to protect a gate oxide layer included in a low-voltage transistor. However, this is only an example embodiment and the present inventive concept is not limited thereto, and the antenna diodes Da, Db1, and Db2 may also be used as components for protecting semiconductor devices other than the low-voltage transistor.

Meanwhile, the antenna diodes Da, Db1, and Db2 for protecting the plurality of transistors may include a first antenna diode Da formed in the first well region PWELL including a first conductivity-type impurity, among the plurality of well regions PWELL and NWELL and second antenna diodes Db1 and Db2 formed on the ion implantation regions IIP.

The plurality of antenna diodes Da, Db1, and Db2 may include a second conductivity-type impurity. Specifically, the plurality of antenna diodes Da, Db1, and Db2 may be formed in an active region including a second conductivity-type impurity. The plurality of antenna diodes Da, Db1, and Db2 may form a PN junction adjacent to a configuration including the first conductivity-type impurity.

At least one of the plurality of antenna diodes Da, Db1, and Db2 may overlap the ion implantation region TIP in the first direction (e.g., the Z-direction). For example, the second antenna diodes Db1 and Db2 may overlap the ion implantation region TIP in the first direction. Accordingly, in the second direction (e.g., the Y-direction), the ion implantation region TIP between the plurality of well regions PWELL and NWELL may be continuously disposed.

The antenna diodes Da, Db1, and Db2 may be connected to the upper metal wiring ML through a plurality of contacts. The metal wiring ML may extend to upper portions of the gate structures GSn and GSp of the transistor in the second direction. The gate structures GSn and GSp of the transistor may be connected to the antenna diodes Da, Db1, and Db2 through a contact and the metal wiring ML. For example, the metal wiring ML may include at least one conductive material selected from among aluminum (Al), copper (Cu), and tungsten (W).

In the semiconductor device according to an embodiment of the present inventive concept, since the antenna diodes Da, Db1, and Db2 are inserted, while minimizing an increase in the interval between the adjacent well regions PWELL and NWELL, the antenna diodes Da, Db1, and Db2 may be formed to be adjacent to the WELL regions, thereby increasing diode efficiency.

Also, the gate structures GSn and GSp of the transistors included in the semiconductor device may be electrically connected to the most adjacent antenna diode among the plurality of antenna diodes Da, Db1 and Db2 through the metal wiring ML. Accordingly, the semiconductor device may reduce routing complexity of the metal wiring ML.

In the semiconductor device according to an embodiment of the present inventive concept, by using the antenna diodes Da, Db1, and Db2 disposed on the ion implantation region IIP, when charges or current are generated according to discharge during a subsequent process of the semiconductor device using plasma or the like, the generated charges or current may be discharged to the antenna diodes Da, Db1, and Db2, thereby minimizing damage to the gate structures GSn and GSp.

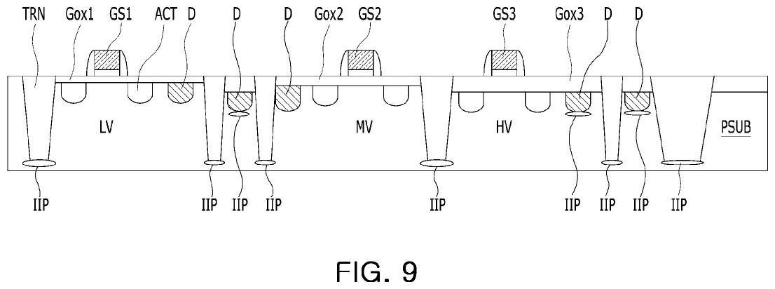

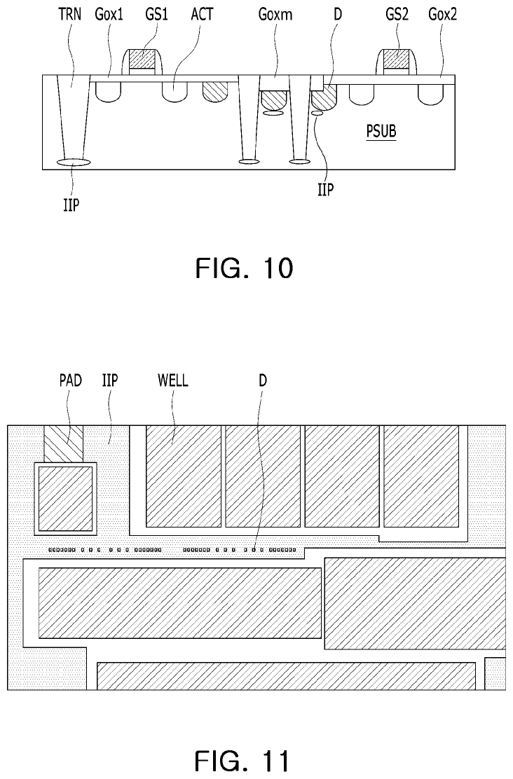

FIG. 9 is a cross-sectional view illustrating a semiconductor device according to an embodiment of the present inventive concept. FIG. 10 is a cross-sectional view illustrating a semiconductor device according to an embodiment of the present inventive concept.

Referring to FIG. 9, a semiconductor device according to an example embodiment may include various types of transistors LV, MV, and HV formed on a semiconductor substrate PSUB. The antenna diode D included in the semiconductor device may be used to protect a gate oxide layer Gox1 of a low-voltage transistor LV. However, this is only an example embodiment and the present inventive concept may not be limited thereto. For example, the antenna diode D may also be used for the purpose of protecting the gate oxide layers Gox2 and Gox3 of the transistors MV and HV other than the low-voltage transistor LV.

The transistors LV, MV, and HV may be separated from each other by a device separation region TRN formed by a shallow trench isolation (STI) or deep trench isolation (DTI) process.

The device separation region TRN may define active regions ACT in the semiconductor substrate PSUB. The device separation region TRN may include a region extending deeper in the semiconductor substrate PSUB between the adjacent active regions ACT, but the present inventive concept is not limited thereto. The device separation region TRN may be formed of an insulating material, and may include, for example, oxide, nitride, or a combination thereof.

The active regions ACT are defined by the device separation region TRN in the semiconductor substrate PSUB and may be disposed to extend in a third direction (e.g., the X-direction). The active region ACT disposed on both sides of the gate structures GS1, GS2, and GS3 may function as a source/drain region.

Meanwhile, in the semiconductor device according to an embodiment of the present inventive concept, active regions ACT other than the active regions ACT disposed on both sides of the gate structures GS1, GS2, and GS3 may function as regions for forming an antenna diode.

In some embodiments, the active regions ACT may have doped regions including impurities. However, a shape of the active regions ACT may not be limited to a structure in which the active regions ACT have a flat upper surface as illustrated.

The active region ACT may be formed of an epitaxial layer, and may include, for example, silicon (Si), silicon germanium (SiGe), or silicon carbide (SiC). In addition, the active region ACT may further include impurities such as arsenic (As) and/or phosphorus (P). In example embodiments, the active region ACT may include a plurality of regions including elements and/or doping elements having different concentrations.

The gate structures GS1, GS2, and GS3 may be disposed to overlap the active regions ACT on top of the active regions ACT and extend in the third direction. Channel regions of transistors may be formed in the active regions ACT overlapping the gate structures GS1, GS2, and GS3. The gate structures GS1, GS2, and GS3 may include a gate insulating layer, a gate electrode layer, gate spacer layers, and a gate capping layer. However, a shape and configuration of the gate structure GS included in each transistor may not be limited to those illustrated.

Gate oxide layers Gox1, Gox2, and Gox3 may be disposed on the semiconductor substrate PSUB on which the transistors are formed. Meanwhile, a thickness of the gate oxide layers Gox1, Gox2, and Gox3 may vary depending on the type of transistor. In the semiconductor device according to an embodiment of the present inventive concept, the plurality of antenna diodes D may be applied to various types of transistors.

Accordingly, a thickness of the gate oxide layers Gox1, Gox2, and Gox3 disposed on any one of the plurality of antenna diodes D may be different from a thickness of the gate oxide layers Gox1, Gox2, and Gox3 disposed on another one among the plurality of antenna diodes D. For example, the thickness of the gate oxide layer Gox1 corresponding to the low-voltage transistor LV using the antenna diode D may be less than the thickness of the gate oxide layers Gox2 and Gox3 corresponding to the other transistors MV and HV using another antenna diode D.

Although not illustrated in FIG. 9, the plurality of antenna diodes D may be connected to contacts passing through the gate oxide layers Gox1, Gox2, and Gox3. The contact may be electrically connected to the gate structures GS1, GS2, and GS3 of the transistor adjacent to the contact through A metal wiring.

Referring to FIG. 10, in the semiconductor device according to an embodiment of the present inventive concept, at least one of the plurality of antenna diodes D may be formed to partially overlap the ion implantation region IIP.

For example, a thickness of the first gate oxide layer Gox1 corresponding to the first gate structure GS1, a thickness of the second gate oxide layer Gox2 corresponding to the second gate structure GS2, and a thickness of the gate oxide layer Goxm therebetween may be different. Any one antenna diode D may be formed under the gate oxide layers Goxm and Gox2 having different thicknesses. In this case, the ion implantation region IIP may partially overlap the corresponding antenna diode D.

However, the structure and shape of the semiconductor device illustrated in FIGS. 9 and 10 are merely an example and the present inventive concept may not be limited. For example, the semiconductor device may further include additional components, some components thereof may be omitted, and the shapes of some components thereof may be changed.

FIG. 11 is a top view illustrating an application example of a semiconductor device according to an embodiment of the present inventive concept.

Referring to FIG. 11, a semiconductor device according to an example embodiment may include a pad region PAD, an ion implantation region IIP, a plurality of well regions WELL, and a plurality of antenna diodes D. The pad region PAD may be a region in which a plurality of pads for inputting and outputting control signals and data are formed. The characteristics of the semiconductor device described above with reference to FIGS. 5 to 10 may be applied to the ion implantation region IIP, the plurality of well regions WELL, and the plurality of antenna diodes D.

Meanwhile, although to be deformed to be applied according to example embodiment, the ion implantation region IIP, the plurality of well regions WELL, and the plurality of antenna diodes D may implement various semiconductor devices formed in a circuit region. That is, the plurality of antenna diodes D may prevent damage to a semiconductor device formed in the plurality of well regions WELL, for example, a transistor.

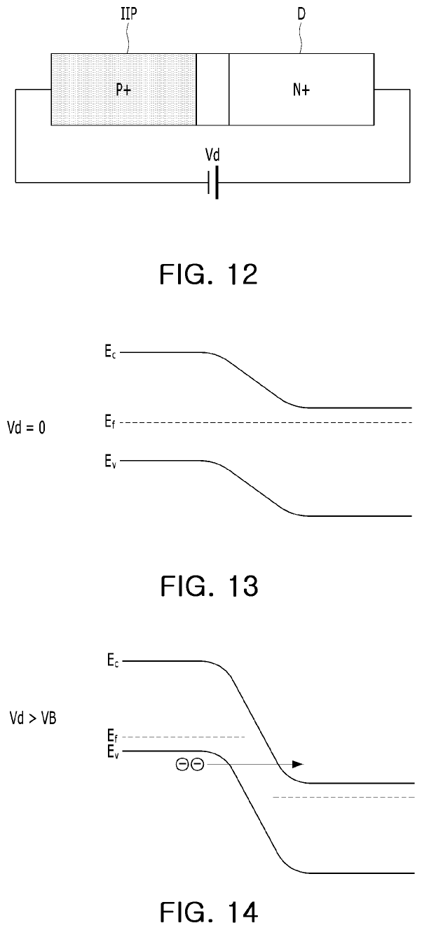

FIGS. 12 to 14 are diagrams illustrating characteristics of an antenna diode included in a semiconductor device according to an embodiment of the present inventive concept.

Referring to FIGS. 12 to 14, the antenna diode D included in the semiconductor device according to an embodiment of the present inventive concept may be formed by junction of a P+ doped region and an N+ doped region. The antenna diode D may include a second conductivity-type impurity, for example, an N+ dopant.

Referring to FIG. 8 together, the first antenna diode Da formed in the first well region PWELL may form a Zener diode based on a PN junction with the first well region PWELL. Meanwhile, the second antenna diodes Db1 and Db2 formed on the ion implantation region IIP may form a Zener diode based on a PN junction with the ion implantation region IIP.

FIG. 12 illustrating modeling of a PN junction diode illustrates a P+ doped region and an N+ doped region to which a diode voltage Vd is applied, and a depletion region therebetween. The diode voltage Vd may correspond to a potential difference between the P+ doped region and the N+ doped region formed by the charge accumulated in the gate electrode, for example, a positive charge.

When positive charges are accumulated in the gate electrode, it may be modeled such that a positive voltage is provided as the diode voltage Vd by the N+ doped region including conductors and the metal wiring ML. Accordingly, as the number of positive charges accumulated in the gate electrode increases, a magnitude of the diode voltage Vd applied in the reverse direction may also increase.

FIG. 13 may be an energy band diagram of a PN junction diode in a state in which the diode voltage Vd is 0V. When a bias voltage is not applied to the high-concentration PN junction diode, a conduction band energy level Ec, a valence band energy level Ev, and a Fermi level Ef may be as illustrated in FIG. 13. In this case, in a state in which the bias is removed, both sides of the Fermi level Ef may have the same value as illustrated in FIG. 13.

FIG. 14 may be an energy band diagram when the diode voltage Vd is lower than a breakdown voltage VB. In other words, the energy level illustrated in FIG. 14 may be an energy level in a situation in which an absolute value of the diode voltage Vd applied in a reverse direction is greater than the breakdown voltage VB. In this case, the Fermi level Ef in the P+ doped region and the Fermi level (Ef) in the N+ doped region may vary.

When the reverse voltage is greater than the breakdown voltage VB, a reverse bias voltage may increase to form a very high electric field in the depletion region. The degree of bending of the energy band of the depletion region may be increased by the large intensity of the electric field. In this case, the energy band in the depletion region may be thin, and band-to-band tunneling of charges may easily occur. Accordingly, when the reverse voltage is greater than the breakdown voltage VB, a large current may flow.

In the semiconductor device according to an embodiment of the present inventive concept, the antenna diode may form a Zener diode having a relatively low breakdown voltage by bonding an N+ doped region to an upper portion of the P+ doped region. Meanwhile, a carrier concentration at the time of yielding may be increased by implanting ions at a high concentration into the doped region. Accordingly, even if the amount of charge accumulated in the antenna diode is large, an upper limit of a bypass current is high, so that the accumulated charge may be quickly removed.

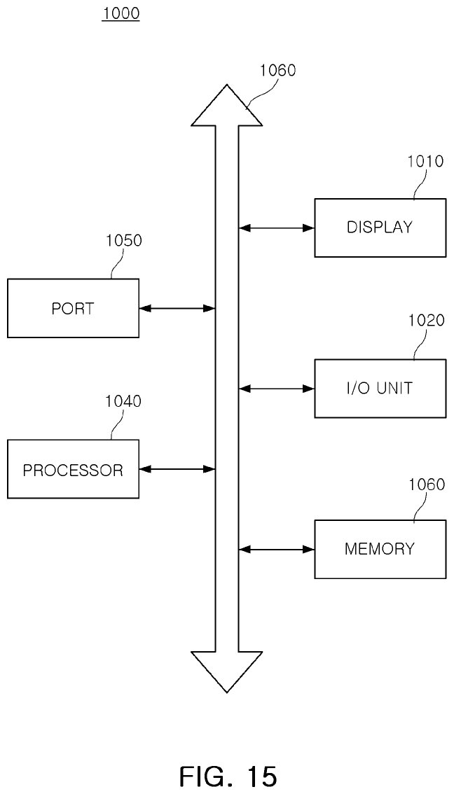

FIG. 15 is a block diagram illustrating an electronic device including a semiconductor device according to an example embodiment.

An electronic device 1000 according to the embodiment illustrated in FIG. 15 may include a display 1010, an input/output(I/O) unit 1020, a memory 1030, a port 1040, a processor 1050, and the like. In addition, the electronic device 1000 may further include a wired/wireless communication device, a power supply device, and the like. Among the components illustrated in FIG. 15, the port 1040 may be a device provided for the electronic device 1000 to communicate with a video card, a sound card, a memory card, a USB device, and the like. The electronic device 1000 may be a concept that encompasses a smartphone, a tablet PC, a smart wearable device, and the like, in addition to a general desktop computer or laptop computer.

The processor 1050 may perform a specific operation, an instruction, a task, or the like. The processor 1050 may be a central processing unit (CPU) or a microprocessor unit (MCU) and may communicate with other devices connected to the port 1040, as well as the display 1010, the I/O unit 1020, and the semiconductor device 1030 through a bus 1060.

The memory 1030 may be a storage medium for storing data necessary for an operation of the electronic device 1000 or multimedia data. The memory 1030 may be a NAND flash memory having a COP structure as described above with reference to FIG. 5. However, this is only an example embodiment and the present inventive concept may not be limited, and the memory 1030 may have a concept including a non-volatile memory having a different structure and configuration or a volatile memory such as a random access memory (RAM). Also, the memory 1030 may include at least one of a solid state drive (SSD), a hard disk drive (HDD), and an optical drive (ODD), as a storage device.

The semiconductor device according to an embodiment of the present inventive concept may be applied to components including transistors formed through a semiconductor process, such as the display 1010, the I/O unit 1020, the memory 1030, and the processor 1050. That is, in order to provide an antenna diode electrically connected to the gate structure of the transistors, while minimizing an increase in an interval between well regions, the antenna diode may be disposed on top of the ion implantation region formed between the well regions. In addition, the gate structure of the transistors may be connected to the most adjacent antenna diode to reduce complexity of the metal wiring.

In the semiconductor device according to an embodiment of the present inventive concept, by forming an antenna diode on the ion implantation region, the antenna diode for protecting the gate oxide layer of the low-voltage transistor may be inserted, while minimizing an increase in a gap between the well regions.

In the semiconductor device according to an embodiment of the present inventive concept, an antenna diode may be inserted, while minimizing an increase in the area of a well region of a peripheral circuit in a memory semiconductor device having a COP (Cell On Peri) structure in which a large amount of plasma is generated during a manufacturing process.

In the semiconductor device according to an embodiment of the present inventive concept, the complexity of the metal wiring connected to the antenna diode may be reduced by forming the antenna diode on the ion implantation region.

The structure being protected by the antenna diode need not be a gate oxide or gate structure, but can be any layer or portion of the device that might suffer damage when exposed to plasma. The semiconductor device need not be COP (Cell On Peri) structure, but can be any bonded multi-wafer approach, or any 3D NAND structure that could benefit from the example embodiments herein (e.g. CMOS under array, periphery under cell array, etc.), or 2D NAND, 4D NAND.

And the semiconductor device need not be a NAND device (SLC, MLC, TLC, QLC etc) at all, as other semiconductor devices are envisioned, such as ones with many metal layers, or other type of memory (NOR FLASH, RAM e.g. DRAM, eDRAM, SRAM, STT-MRAM, FeRAM, NRAM, ReRAM, OxRAM, CBRAM, MRAM, PCRAM, XPoint, eFLASH, etc) that might suffer from plasma degradation during fabrication where an antenna diode can prove helpful.

A solid state drive incorporating a NAND device as in the exemplary embodiments herein can be an internal solid state hard drive of a computer, an external SSD hard drive or USB key, a SSD in a cell phone, tablet, video game console, enterpriser server systems, data center, etc or other electronic device or storage configuration with a solid state hard drive.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a memory cell region including a plurality of memory cells disposed on a first semiconductor substrate and including gate electrodes stacked to be spaced apart from each other on the first semiconductor substrate and channel structures passing through the gate electrodes and connected to the first semiconductor substrate;
a peripheral circuit region including a first conductivity-type impurity, disposed on a second semiconductor substrate having an upper surface facing to an upper surface of the first semiconductor substrate in a first direction, perpendicular to the upper surface of the first semiconductor substrate, and including peripheral circuits controlling the plurality of memory cells;
wherein the peripheral circuits include a plurality of well regions formed in the second semiconductor substrate, an ion implantation region disposed between the plurality of well regions and including the first conductivity-type impurity, and a plurality of antenna diodes; and
at least one of the plurality of antenna diodes overlaps the ion implantation region in the first direction.

2. The semiconductor device of claim 1, wherein the plurality of well regions include a first well region including the first conductivity-type impurity and a second well region including a second conductivity-type impurity, different from the first conductivity-type impurity.

3. The semiconductor device of claim 2, wherein the plurality of antenna diodes include a first antenna diode formed in the first well region and a second antenna diode disposed between the plurality of well regions.

4. The semiconductor device of claim 1, wherein the plurality of antenna diodes include a second conductivity-type impurity, different from the first conductivity-type impurity.

5. The semiconductor device of claim 1, wherein a doping concentration of the ion implantation region is higher than a doping concentration of the plurality of well regions.

6. The semiconductor device of claim 1, wherein a concentration of the first conductivity-type impurity included in the ion implantation region is different according to positions.

7. The semiconductor device of claim 1, wherein the ion implantation region is continuously disposed between the plurality of well regions in a second direction, perpendicular to the first direction.

8. The semiconductor device of claim 1, wherein a gate oxide layer is disposed on the second semiconductor substrate, and a thickness of the gate oxide layer disposed on any one of the plurality of antenna diodes is different from a thickness of a gate oxide layer disposed on another one of the plurality of antenna diodes.

9. The semiconductor device of claim 8, wherein the plurality of antenna diodes are connected to a contact passing through the gate oxide layer, and the contact is electrically connected to a gate structure of a transistor adjacent to the contact through a metal wiring.

10. The semiconductor device of claim 9, wherein the plurality of antenna diodes discharge plasma ions accumulated near the transistor connected through the metal wiring.

11. The semiconductor device of claim 1, wherein at least one of the plurality of antenna diodes partially overlaps the ion implantation region.

12. The semiconductor device of claim 1, wherein each of the plurality of well regions includes an active region including a conductivity-type impurity having a conductivity type different from that of an impurity included in each of the plurality of well regions, and the active region and gate structures formed on the active region define a plurality of transistors included in the peripheral circuits.

13. The semiconductor device of claim 12, wherein the plurality of transistors are separated from each other by a device separation region.

14. The semiconductor device of claim 12, wherein a transistor, among the plurality of transistors, adjacent to an antenna diode disposed between the plurality of well regions, among the plurality of antenna diodes, is a low-voltage transistor.

15. The semiconductor device of claim 1, wherein the first conductivity-type impurity is an N-type dopant.

16. A semiconductor device comprising:
a plurality of well regions formed on a semiconductor substrate including a first conductivity-type impurity and including a first well region including the first conductivity-type impurity and a second well region including a second conductivity-type impurity, different from the first conductivity-type impurity;
an ion implantation region disposed between the plurality of well regions and including the first conductivity-type impurity;
a plurality of antenna diodes including a first antenna diode formed in the first well region and a second antenna diode disposed on the ion implantation region; and
a plurality of transistors, each of the plurality of transistors being defined by an active region included in the plurality of well regions and a gate structure formed on the active region.

17. The semiconductor device of claim 16, wherein the ion implantation region is continuously disposed between the plurality of well regions.

18. The semiconductor device of claim 16, wherein a doping concentration of the ion implantation region is higher than a doping concentration of the first well region.

19. The semiconductor device of claim 16, wherein the gate structure is electrically connected to at least one of the plurality of antenna diodes.

20. A semiconductor device comprising:
a plurality of well regions formed in a semiconductor substrate including a first conductivity-type impurity;
an ion implantation region disposed between the plurality of well regions and including the first conductivity-type impurity;
a plurality of antenna diodes, at least one of the plurality of antenna diodes being disposed on the ion implantation region; and
a plurality of transistors, each of the plurality of transistors being defined by an active region included in the plurality of well regions and a gate structure formed on the active region, the gate structure being electrically connected to a most adjacent antenna diode, among the plurality of antenna diodes, by a metal wiring.

21. (canceled)
